(19) United States
(12) Patent Application Publication
(10) Pub. No.: US 2008/0230210 A1
(43) Pub. Date: Sep. 25, 2008

(54) Thermosiphon boiler plate

(76) Inventors: Mohinder Singh Bhatti, Amherst, NY (US); Ilya Reyzin, Williamsville, NY (US); Shrikant Mukund Joshi, Williamsville, NY (US)

Correspondence Address: DELPHI TECHNOLOGIES, INC., M/C 480-410-202, PO BOX 5052, TROY, MI, 48007, US

(21) Appl. No.: 11/726,208

(22) Filed: Mar. 21, 2007

(51) Int. Cl. H01L 23/34; H05K 7/20

(52) U.S. Cl. 165/104.33; 165/185; 165/906; 361/700

(57) ABSTRACT

A thermosiphon boiler plate assembly (20) for dissipating heat generated by an electronic device includes a plurality of widthwise ribs (38) disposed on a top surface (26) of a base (24) extending parallel to a latitudinal axis (Aₓ) of the base (24) in spaced relationship to each other. A plurality of lengthwise ribs (40) are disposed on the top surface (26) of the base (24) extending parallel to a longitudinal axis (A_{y}) of the base (24) in spaced relationship to each other. The lengthwise ribs (40) intersect the widthwise ribs (38) on the top surface (26) of the base (24) to define a plurality of pockets (42) completely surrounded by the lengthwise and widthwise ribs (40, 38) to increase the widthwise and lengthwise area moments of inertia (Iₓ, I_{y}) of the assembly (20).

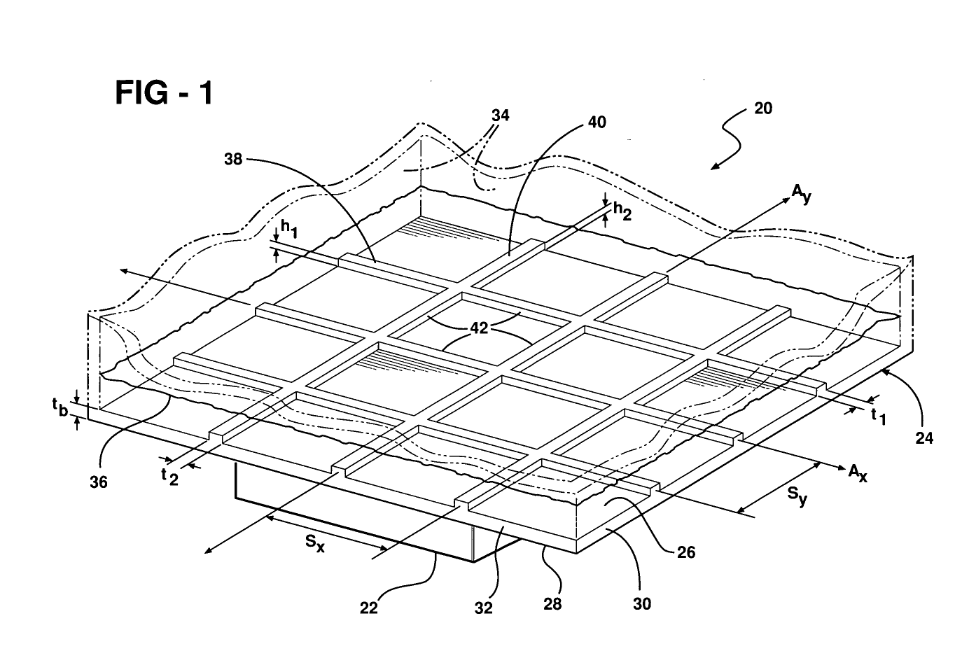

### BACKGROUND OF THE INVENTION

1. Field of the Invention

The subject invention relates to a thermosiphon boiler plate assembly for dissipating heat generated by an electronic device, and more specifically, to a low profile thermosiphon boiler plate assembly having a high plate strength.

2. Description of the Prior Art

Boiler plates have traditionally been used in electronic apparatuses to dissipate heat from electrical components. A boiler plate is a device that attaches directly to an electrical device to enhance the dissipation of heat therefrom. A boiler plate is generally designed with a base for contacting an electrical device and a means for dissipating the heat transferred from the device to the boiler plate. An example of such a boiler plate is disclosed in U.S. Pat. No. 6,179,046 to Hwang et al. The Hwang et al. patent discloses a base having a top surface and a bottom surface and a plurality of spaced fins disposed on the top surface of the base. The spaced fins are disposed radially around a circumference of a circular central portion of the base and extend radially outward from the circumference of the circular central portion along the top surface of the base. Heat is transferred from an electrical device to the base, and the base transfers the heat from the fins to the exterior environment.

An additional example of a boiler plate is disclosed in U.S. Pat. No. 6,140,571 to Kitahara et al. The Kithara et al. patent discloses a base having a top surface and a bottom surface. The base has a longitudinal axis extending along the top surface of the base equidistant from a pair of width edges and a latitudinal axis extending along the top surface of the base equidistant from a pair of length edges and perpendicular to said longitudinal axis. A first partition plate is disposed on the top surface extending along the longitudinal axis and a second partition plate is disposed on the top surface extending along the latitudinal axis intersecting the first partition plate. A fan is disposed above the top surface of the base to propel air towards the top surface of the base. The partition plates restrict the path of the propelled air to the outside of the heat sink to prevent a reduction of the cooling efficiency by the mutual collision of the cooling air.

Recent advances in electrical components have led to decreasing device size and increasing capabilities which has resulted in an increasing of package densities and heat generation rate. In recent electronic apparatuses, the increasing package densities have led to a decreasing package size allowing for a diminishing amount of space to effectively dissipate heat generated by the electrical components within the electronic apparatuses. The available space for dissipating heat has become narrower, and the heat radiation within electronic apparatuses has become an increasingly difficult problem.

### SUMMARY OF THE INVENTION AND ADVANTAGES

The present invention provides for a thermosiphon boiler plate assembly for dissipating heat generated by an electronic device comprising a base having a top surface and a bottom surface for absorbing heat generated by the electronic device, a plurality of widthwise ribs disposed on the top surface of the base, and a plurality of lengthwise ribs disposed on the top surface of the base. The lengthwise ribs intersect the widthwise ribs on the top surface of the base to define a plurality of pockets on the top surface completely surrounded by the lengthwise and widthwise ribs to increase the widthwise and lengthwise area moment of inertia of the assembly for resisting deflection of the assembly.

The present invention provides a thermosiphon boiler plate assembly that has a low profile, high heat transfer rate, high plate strength, and low plate mass.

### BRIEF DESCRIPTION OF THE DRAWINGS

Other advantages of the present invention will be readily appreciated, as the same becomes better understood by reference to the following detailed description when considered in connection with the accompanying drawing wherein the FIGURE is a perspective view of a thermosiphon boiler plate assembly.

### DETAILED DESCRIPTION OF THE INVENTION

Referring to the FIGURE, wherein like numerals indicate corresponding parts throughout the several views, a thermosiphon boiler plate assembly 20 is generally shown for dissipating heat generated by an electronic device 22.

The thermosiphon boiler plate assembly 20 comprises a base 24 generally indicated having a top surface 26 and a bottom surface 28 and a rectangular periphery thereabout. The bottom surface 28 contacts the electronic device 22 to absorb heat generated by the electronic device 22. The periphery is defined be a pair of length edges 30 and a pair of width edges 32 extending between the surfaces 26, 28. In an embodiment of the invention as shown in the FIGURE, the length edges 30 and the width edges 32 are equal in length defining the periphery of the base 24 as a square.

The length edges 30 and the width edges 32 define a base thickness t_{b} between the surfaces 26, 28. The base thickness t_{b} is proportional to a thermal resistance R of the base 24 as defined by the equation:

R=t_{b}/(kA)

where “k” is the thermal conductivity of the material of the base 24 and “A” is the surface area of the base 24. In the preferred embodiment, the thermal resistance R of the base 24 should be as low as possible to establish a high heat transfer rate to effectively dissipate heat. The base thickness t_{b} is preferably in the range of 0.5 to 1 millimeters.

A chamber 34 is disposed about the top surface 26 of the base 24 for containing a refrigerant 36 for liquid-to-vapor transformation. Heat generated by the electronic device 22 is absorbed by the base 24 and transferred to the refrigerant 36 contained within the chamber 34. The refrigerant 36 is evaporated by the heat and the resultant vapor is later condensed and returned to the chamber 34.

As shown in the FIGURE, the base 24 has a latitudinal axis Aₓ extending along the top surface 26 equidistant from the width edges 32 and perpendicular to the length edges 30. The base 24 also has a longitudinal axis A_{y} extending along the top surface 26 equidistant from the length edges 30 and perpendicular to the width edges 32 and perpendicular to the latitudinal axis Aₓ.

A plurality of widthwise ribs 38 are disposed on the top surface 26 of the base 24 to reinforce the assembly 20. Widthwise ribs 38 of various densities can be used to match the heat flux footprint of the heat generating device. The widthwise ribs 38 preferably extend parallel to the latitudinal axis Aₓ in spaced relationship to each other between the length edges 30. In an embodiment as shown in the FIGURE, one of the widthwise ribs 38 extends axially along the latitudinal axis Aₓ and each of the widthwise ribs 38 are spaced from adjacent widthwise ribs 38 a widthwise distance s_{y}. Each of the widthwise ribs 38 first adjacent each of the width edges 32 are spaced the widthwise distance s_{y} from the adjacent width edges 32 as shown in the FIGURE. The widthwise distance s_{y} can be varied to vary a widthwise elastic constant Dₓ of the assembly 20. The widthwise elastic constant Dₓ of the assembly 20 is defined by the equation:

Dₓ=E/(12(1−v²))*EI_{y}/s_{y}

where “E” is Young's modulus, “v” is Poisson's ratio, and “I_{Y}” is a lengthwise area moment inertia of the assembly 20 expressed as:

I_{y}=t₂(h₂+t_{B}/2)³/12

where “t₂” is a second rib thickness and “h₂” is a second rib height. The widthwise distance s_{y} divided by the base thickness t_{b} is a first distance ratio preferably in the range of 1 to 6 as a factor in the widthwise elastic constant Dₓ of the assembly 20. The significance of the widthwise elastic constant Dₓ is that it is an elastic parameter which determines the deflection of the assembly 20 along the latitudinal axis Aₓ. The greater the value of the widthwise elastic constant Dₓ, the greater the resistance of the assembly 20 to deflection along the latitudinal axis Aₓ. The deflection of the assembly 20 along the latitudinal axis Aₓ is inversely proportional to the widthwise elastic constant Dₓ.

Each of the widthwise ribs 38 have a rib cross-section defining a first rib height h₁ and a first rib thickness t₁. The first rib height h₁ and the first rib thickness t₁ can be varied to vary a widthwise area moment of inertia Iₓ of the assembly 20. The widthwise area moment of inertia Iₓ of the assembly 20 is defined by the equation:

Iₓ=t₁(h₁+t_{b}/2)³/12

and the first rib thickness t₁ divided by the base thickness t_{b} is a first thickness ratio in the range of 1 to 2 as a factor in the widthwise area moment of inertia Iₓ of the assembly 20. The first rib height h₁ divided by the base thickness t_{b} is a first height ratio greater than 0 and not greater than 4 as a factor in the widthwise area moment of inertia Iₓ of the assembly 20.

A plurality of lengthwise ribs 40 are disposed on the top surface 26 of the base 24 intersecting the widthwise ribs 38 on the top surface 26 of the base 24 to define a plurality of pockets 42 on the top surface 26 completely surrounded by the lengthwise and widthwise ribs 40, 38 to reinforce the assembly 20. The plurality of pockets 42 defined by the intersection of the lengthwise and widthwise ribs 40, 38 are completely surrounded on all sides as shown in the FIGURE. Lengthwise ribs 40 having various densities can be used to match the heat flux footprint of the heat generating device.

The lengthwise ribs 40 preferably extend parallel to the longitudinal axis A_{y} in spaced relationship to each other between the width edges 32. In an embodiment as shown in the FIGURE, one of the lengthwise ribs 40 extends axially along the longitudinal axis A_{y} and each of the lengthwise ribs 40 are spaced from adjacent lengthwise ribs 40 a lengthwise distance sₓ. Each of the lengthwise ribs 40 first adjacent each of the length edges 30 are spaced the lengthwise distance sₓ from the adjacent length edges 30 as shown in the FIGURE. In an embodiment as shown in the FIGURE, the lengthwise distance sₓ is equal to the widthwise distance s_{y} defining each pocket 42 as being a square. The lengthwise distance sₓ can be varied to vary a lengthwise elastic constant D_{y} of the assembly 20. The lengthwise elastic constant D_{y} of the assembly 20 is defined by the equation:

D_{y}=E/(12(1−v²))+EIₓ/(sₓt_{b}³)

where “E” is Young's modulus and “v” is Poisson's ratio. The lengthwise distance sₓ divided by the base thickness t_{b} is a second distance ratio preferably in the range of 1 to 6 as a factor in the lengthwise elastic constant D_{y} of the assembly 20. The significance of the lengthwise elastic constant D_{y} is that it is an elastic parameter which determines the deflection of the assembly 20 along the longitudinal axis A_{y} in that the lengthwise elastic constant D_{y} is inversely proportional to the deflection of the assembly 20 along the longitudinal axis A_{y}. The deflection of the assembly 20 is inversely proportional to the square root of the widthwise elastic constant Dₓ times the lengthwise elastic constant D_{y}.

Each of the lengthwise ribs 40 have a rib cross-section defining the second rib height h₂ and the second rib thickness t₂. In the embodiment shown in the FIGURE, the second rib height h₂ is equal to the first rib height h₁ and the second rib thickness t₂ is equal to the first rib thickness t₁. In alternative embodiments, the second rib height h₂ and the second rib thickness t₂ can be varied to vary the lengthwise area moment of inertia I_{y} of the assembly 20. The lengthwise area moment of inertia I_{y} of the assembly 20 is defined by the equation:

I_{y}=t₂(h₂+t_{B}/2)³/12.

The second rib thickness t₂ divided by the base thickness t_{b} is a second thickness ratio in the range of 1 to 2 as a factor in the lengthwise area moment of inertia I_{y} of the assembly 20. The second rib height h₂ divided by the base thickness t_{b} is a second height ratio greater than 0 and not greater than 4 as a factor in the lengthwise area moment of inertia I_{y} of the assembly 20.

While the invention has been described with reference to an exemplary embodiment, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

What is claimed is:

1. A thermosiphon boiler plate assembly for dissipating heat generated by an electronic device comprising;
a base having a top surface and a bottom surface for absorbing heat generated by the electronic device,
a plurality of widthwise ribs disposed on said top surface of said base,
a plurality of lengthwise ribs disposed on said top surface of said base, and
said lengthwise ribs intersecting said widthwise ribs on said top surface of said base to define a plurality of pockets on said top surface completely surrounded by said lengthwise and widthwise ribs to increase a widthwise area moment of inertia and a lengthwise area moment of inertia of said assembly for resisting deflection of said assembly.

2. An assembly as set forth in claim 1 including a chamber disposed about said top surface of said base for containing a refrigerant for liquid-to-vapor transformation.

3. An assembly for dissipating heat as set forth in claim 2 wherein said base has a periphery about said top and bottom surfaces defined by a pair of length edges and a pair of width edges defining a base thickness between said top and bottom surfaces in the range of 0.5 to 1 millimeters.

4. An assembly as set forth in claim 3 wherein said periphery is rectangular.

5. An assembly as set forth in claim 4 wherein said length edges and said width edges are equal in length.

6. An assembly as set forth in claim 3 wherein each of said widthwise ribs have a first rib height with said first rib height divided by said base thickness being a first height ratio greater than 0 and not greater than 4 as a factor in the widthwise area moment of inertia of said assembly.

7. An assembly as set forth in claim 6 wherein each of said lengthwise ribs have a second rib height with said second rib height divided by said base thickness being a second height ratio greater than 0 and not greater than 4 as a factor in the widthwise area moment of inertia of said assembly.

8. An assembly as set forth in claim 7 wherein said second rib height is equal to said first rib height.

9. An assembly as set forth in claim 3 wherein each of said widthwise ribs have a first rib thickness with said first rib thickness divided by said base thickness being a first thickness ratio in the range of 1 to 2 as a factor in the widthwise area moment of inertia of said assembly.

10. An assembly as set forth in claim 9 wherein each of said lengthwise ribs have a second rib thickness with said second rib thickness divided by said base thickness being a second thickness ratio in the range of 1 to 2 as a factor in the widthwise area moment of inertia of said assembly.

11. An assembly as set forth in claim 10 wherein said second rib thickness is equal to said first rib thickness.

12. An assembly as set forth in claim 3 wherein each of said widthwise ribs are spaced from adjacent widthwise ribs a widthwise distance.

13. An assembly as set forth in claim 12 wherein said widthwise distance divided by said base thickness is a first distance ratio in the range of 1 to 6 as a factor in a widthwise elastic constant of said assembly.

14. An assembly as set forth in claim 13 wherein each of said lengthwise ribs are spaced from adjacent lengthwise ribs a lengthwise distance.

15. An assembly as set forth in claim 14 wherein said lengthwise distance divided by said base thickness is a second distance ratio in the range of 1 to 6 as a factor in a lengthwise elastic constant of said assembly.

16. An assembly as set forth in claim 15 wherein said lengthwise distance is equal to said widthwise distance.

17. An assembly as set forth in claim 3 wherein said base has a latitudinal axis extending along said top surface equidistant from said width edges and perpendicular to said length edges with said widthwise ribs extending parallel to said latitudinal axis in spaced relationship to each other between said length edges.

18. An assembly as set forth in claim 17 wherein one of said widthwise ribs extends axially along said latitudinal axis.

19. An assembly as set forth in claim 18 wherein each of said widthwise ribs are spaced from adjacent widthwise ribs a widthwise distance.

20. An assembly as set forth in claim 19 wherein each of said widthwise ribs first adjacent each of said width edges are spaced said widthwise distance from said adjacent width edges.

21. An assembly as set forth in claim 19 wherein said base has a longitudinal axis extending along said top surface equidistant from said length edges and perpendicular to said width edged and perpendicular to said latitudinal axis with said lengthwise ribs extending parallel to said longitudinal axis in spaced relationship to each other between said width edges.

22. An assembly as set forth in claim 21 wherein one of said lengthwise ribs extends axially along said longitudinal axis.

23. An assembly as set forth in claim 22 wherein each of said lengthwise ribs are spaced from adjacent lengthwise ribs a lengthwise distance.

24. An assembly as set forth in claim 23 wherein each of said lengthwise ribs first adjacent each of said length edges are spaced said lengthwise distance from said adjacent length edges.

25. An assembly as set forth in claim 23 wherein said lengthwise distance is equal to said widthwise distance.

26. An assembly as set forth in claim 25 wherein said widthwise ribs have a rib cross-section defining a first rib height and a first rib thickness and said lengthwise ribs have a rib cross-section defining a second rib height and a second rib thickness with said second rib thickness being equal to said first rib thickness.

27. An assembly as set forth in claim 26 wherein said first rib height is equal to said second rib height.

28. A thermosiphon boiler plate assembly for dissipating heat generated by an electronic device comprising;
a base having a top surface and a bottom surface for absorbing heat generated by the electronic device and a rectangular periphery thereabout,
said periphery defined by a pair of length edges and a pair of width edges defining a base thickness between said top and bottom surfaces in the range of 0.5 to 1 millimeters,
said length edges and said width edges being equal in length,
a chamber disposed about said top surface of said base for containing a refrigerant for liquid-to-vapor transformation,
said base having a latitudinal axis extending along said top surface equidistant from said width edges and perpendicular to said length edges,
said base having a longitudinal axis extending along said top surface equidistant from said length edges and perpendicular to said width edges and perpendicular to said latitudinal axis,
a plurality of widthwise ribs disposed on said top surface of said base,
said widthwise ribs extending parallel to said latitudinal axis in spaced relationship to each other between said length edges,
one of said widthwise ribs extending axially along said latitudinal axis,
each of said widthwise ribs being spaced from adjacent widthwise ribs a widthwise distance,
said widthwise distance divided by said base thickness being a first distance ratio in the range of 1 to 6 as a factor in a widthwise elastic constant of said assembly,
each of said widthwise ribs first adjacent each of said width edges being spaced said widthwise distance from said adjacent width edges,
each of said widthwise ribs having a rib cross-section defining a first rib height and a first rib thickness,
said first rib thickness divided by said base thickness being a first thickness ratio in the range of 1 to 2 as a factor in a widthwise area moment of inertia of said assembly,
said first rib height divided by said base thickness being a first height ratio greater than 0 and not greater than 4 as a factor in the widthwise area moment of inertia of said assembly,
a plurality of lengthwise ribs disposed on said top surface of said base intersecting said widthwise ribs to define a plurality of pockets surrounded by said lengthwise and widthwise ribs to increase the widthwise area moment of inertia and a lengthwise area moment of inertia of said assembly for resisting deflection of said assembly,
said lengthwise ribs extending parallel to said longitudinal axis in spaced relationship to each other between said width edges,
one of said lengthwise ribs extending axially along said longitudinal axis,
each of said lengthwise ribs being spaced from adjacent lengthwise ribs a lengthwise distance,
each of said lengthwise ribs first adjacent each of said length edges being spaced said lengthwise distance from said adjacent length edges,
said lengthwise distance divided by said base thickness being a second distance ratio in the range of 1 to 6 as a factor in a lengthwise elastic constant of said assembly,
each of said lengthwise ribs having a rib cross-section defining a second rib height and a second rib thickness,
said second rib thickness divided by said base thickness being a second thickness ratio in the range of 1 to 2 as a factor in the lengthwise area moment of inertia of said assembly,
said second rib height divided by said base thickness being a second height ratio greater than 0 and not greater than 4 as a factor in the lengthwise area moment of inertia of said assembly,
said lengthwise distance being equal to said widthwise distance,
said second rib thickness being equal to said first rib thickness, and
said second rib height being equal to said first rib height.
